(19) United States
(12) Patent Application Publication
(10) Pub. No.: US 2009/0039520 A1
(43) Pub. Date: Feb. 12, 2009

(54) SEMICONDUCTOR CIRCUIT DEVICE, WIRING METHOD FOR SEMICONDUCTOR CIRCUIT DEVICE AND DATA PROCESSING SYSTEM

(75) Inventors: Teruya Tanaka, Tokyo (JP); Ko Miyazaki, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/188,465

(22) Filed: Aug. 8, 2008

(30) Foreign Application Priority Data
Aug. 9, 2007 (JP) 2007-207425

(51) Int. Cl. H01L 23/48; G06F 17/50

(52) U.S. Cl. 257/773; 716/9; 257/E21.627

(57) ABSTRACT

Via multiplexing technology is provided which can contribute to high density wiring. For coupling wirings of different wiring layers, a multiple via cell section is used which has vias for electrically coupling wirings bent in an L-shape of different wiring layers on both sides with the L-shaped bent portion therebetween. The vias of the multiple via cell section are on a grid line in an X-direction and a grid line in a Y-direction defined with a minimum wiring pitch, and all or part of the vias of the multiple via cell section are deviated from an intersection of the grid line in the X-direction and the grid line in the Y-direction. The vias of the multiple via cell section are placed on each of the grid line in the X-direction and the grid line in the Y-direction, corresponding to the L-shape, so that there is not much difference between the spatial conditions in the X-direction and the spatial conditions in the Y-direction viewed from the multiple via cell section. Thus, the wirability in the X-direction becomes equivalent to that in the Y-direction.

### CROSS-REFERENCE TO RELATED APPLICATION

The present application claims priority from Japanese patent application No. 2007-207425 filed on Aug. 9, 2007, the content of which is hereby incorporated by reference into this application.

### BACKGROUND OF THE INVENTION

The present invention relates to a wiring technology of electrically coupling wirings of wiring layers adjacent to each other of a semiconductor device using vias.

In the manufacturing process of a semiconductor device, vias have been additionally inserted for coupling wirings of different wiring layers, for example, in order to prevent the yield of the semiconductor device from decreasing due to a random defect by fine particles, a photomask alignment error, or the like.

In Patent Document 1 (Specification of U.S. Pat. No. 5,798,937), a technology of disposing a via and then adding redundant vias next to it is described. In Patent Document 2 (Specification of U.S. Pat. No. 6,026,224), a technology of additionally arranging vias on grids adjacent to and around certain one via is described. The technologies described in the documents are those of additionally arranging redundant vias in addition to a specific via.

In Patent Document 3 (Japanese Unexamined Patent Publication No. 2005-347692), a technology of coupling wirings inclined 45 degrees to each other with vias is described and in particular the structure of a via referred to as a double-cut via is shown. The double-cut via has a via structure formed by performing wiring extension or the like in consideration of the states of wirings around a first via and/or the states of other vias to provide a second via in addition to the first via. The via structure is also formed by a technology of arranging redundant vias in addition to a specific via. Also in Patent Document 4 (Japanese Unexamined Patent Publication No. 2005-109336), a design method of providing redundant vias in addition to the specific via to couple wirings inclined 45 degrees to each other is shown as in Patent Document 3.

### SUMMARY OF THE INVENTION

The present inventors have examined problems in multiplexing vias. Firstly, it has been found out that when wiring is performed on a cell basis, in the case that a plurality of via cells of single vias is arranged to multiplex vias, it must be determined every time each of the via cells is arranged whether spatial conditions are satisfied for the surroundings, and the data processing time becomes longer as the number of multiplexed vias increases. Secondly, when a plurality of vias is arranged linearly along wiring grids, spatial conditions in the arrangement directions are different from those in directions crossing the arrangement directions, which causes nonuniformity of wirability in each of the X-direction and the Y-direction. Thirdly, a rule related to a space between different potential vias which is an interval between vias connected to different potential signal lines is severer than the rule of a minimum pitch of wirings, so that when a plurality of vias is arranged corresponding to intersections of grids respectively, there is a restriction that different potential vias cannot be arranged without being separated at least two grids from the surroundings. These problems are not considered in any of the patent documents. When adopting a design approach of providing redundant vias in addition to a specific via for coupling wirings of different wiring layers to each other, any of the problems cannot be solved.

An object of the present invention is to multiplex vias to shorten the data processing time for wiring connection.

Another object of the present invention is to provide via multiplexing technology which can contribute to high density wiring.

Still another object of the present invention is to provide via multiplexing technology which can contribute to a higher degree of integration of circuit elements.

Still another object of the present invention is to make a restriction to the layout of different potential vias not become severe, the restriction being given to the surroundings of vias by multiplexing the vias.

The above and further objects and novel features of the present invention will be apparent from the following description of this specification and the accompanying drawings.

The outline of a typical one of inventions disclosed in this application will be briefly described below.

For coupling wirings of different wiring layers, a multiple via cell section is used which has vias for electrically coupling wirings bent in an L-shape of different wiring layers on both sides with the L-shaped bent portion therebetween. The vias of the multiple via cell section are on a grid line in an X-direction and a grid line in a Y-direction defined with a minimum wiring pitch, and all or part of the vias of the multiple via cell section are deviated from intersections of grid lines in the X-direction and grid lines in the Y-direction.

The vias of the multiple via cell section are placed on each of the grid line in the X-direction and the grid line in the Y-direction, corresponding to the L-shape, so that there is not much difference between the spatial conditions in the X-direction and the spatial conditions in the Y-direction viewed from the multiple via cell section. This is different from the case that when a plurality of vias is arranged linearly along a wiring grid, spatial conditions for the arrangement direction are much different from spatial conditions for the direction crossing the arrangement direction. Thus, wirability in the X-direction becomes equivalent to that in the Y-direction. The equivalency in wirability results in the equivalency also in layout restriction points for the different potential vias around the multiple via cell section in each of the X-direction and the Y-direction, thus reducing the number of vias to which the restriction is applied. Furthermore, the vias of the multiple via cell section are on grid lines but are deviated from the intersection of the grid lines, so that the cover margins of the vias, that is, the margins allowing deviations of the vias even if the vias are deviated in the wiring directions, substantially increase by the deviations from the intersection, because of relations to the spatial conditions for the surroundings of the vias. This can contribute to high integration of a semiconductor device. Furthermore, each of the multiple via cell sections has a plurality of vias, so that when the multiple via cells are used, the time of the wiring processing can be reduced as compared with data processing of multiplexing vias by adding vias around specific vias in the wiring processing.

Effects obtained by a typical one of inventions disclosed in this application will be briefly described below.

The invention can multiplex vias to shorten the data processing time for wiring connection.

The invention can contribute to higher density wiring.

The invention can contribute to high integration of circuit elements.

The invention can multiplex vias so that a restriction to the layout of different potential vias to the surroundings does not become severe.

### BRIEF DESCRIPTION OF THE DRAWINGS

FIG. 1 is a plan view illustrating a planar structure of a first multiple via cell section;

FIG. 2 is a block diagram illustrating circuit cells disposed in a semiconductor device;

FIG. 3 is a cross-sectional view showing the outline of the longitudinal section structure of the semiconductor device;

FIG. 4 is a perspective view illustrating a structure of the first multiple via cell section;

FIG. 5 is a perspective view illustrating a structure of a second multiple via cell section which is another example of a multiple via cell section;

FIG. 6 is a plan view of the second multiple via cell section;

FIG. 7 is a plan view showing layout restriction points for different potential vias around the first multiple via cell section;

FIG. 8 is a plan view showing layout restriction points of different potential vias around the second multiple via cell section;

FIG. 9 is a plan view illustrating cover margins of vias in the first multiple via cell section;

FIG. 10 is a plan view illustrating an entire cover margin of vias in the first multiple via cell section;

FIG. 11 is a plan view illustrating a planar structure of a single via cell section 22;

FIG. 12 is a perspective view of the single via cell section;

FIG. 13 illustrates the number distribution of single via cell sections between respective wiring layers in the case that the wirings of different wiring layers are coupled by single via cell sections;

FIG. 14 is a plan view illustrating a concrete planar layout of wirings of wiring layers M1 and M2;

FIG. 15 is a plan view illustrating the details of a part A in FIG. 14;

FIG. 16 is a plan view illustrating how to easily couple cell terminals of a circuit cell section to the first multiple via cell section;

FIG. 17 is a block diagram illustrating a data processing system supporting wiring design for a semiconductor device;

FIG. 18 depicts via cell data possessed by via cell database;

FIG. 19 depicts data structures of circuit cells and via cells;

FIG. 20 is a flow chart of wiring design in the design processing of a semiconductor device;

FIG. 21 is a flow chart showing a concrete example of selectively replacing a single via cell with the first multiple via cell;

FIG. 22 is a plan view showing a state that the first multiple via cell obtained by replacement in the processing of FIG. 21 satisfies spatial conditions for the surroundings;

FIG. 23 is a flow chart showing a concrete example of a layout processing of forcibly replacing a single via cell with the first multiple via cell;

FIG. 24 is a plan view showing a state that a wiring in an X-direction and a wiring in a Y-direction are short-circuited;

FIG. 25 is a flow chart showing a procedure in the case that the first multiple via cell is used from an initial layout of via cells;

FIG. 26 is a flow chart showing a procedure of selectively replacing initially arranged single via cells with second multiple via cells and then forcibly replacing single via cells which cannot be replaced with the second multiple via cells with first multiple via cells; and

FIG. 27 is a flow chart showing a procedure of selectively replacing initially arranged single via cells with first multiple via cells and then forcibly replacing single via cells which cannot be replaced with the first multiple via cells with second multiple via cells.

### DETAILED DESCRIPTION OF THE PREFERRED EMBODIMENTS

### 1. Outline of Embodiments

First, the outline of typical embodiments of the present invention disclosed in this application will be described. Reference numerals and symbols in figures referred with parentheses in the outline description about the typical embodiments indicate only examples included in concepts of components to which the reference numerals and symbols are attached.

[1_{—}1] A semiconductor device has: many circuit cell sections (2, 3, 4, CEL) which are regularly arranged over a semiconductor substrate; terminals (Ts, L11, L12) of the arranged circuit cell sections formed in a first wiring layer; and a plurality of via cell sections of a first hierarchy for coupling the terminals of the circuit cell sections to a second wiring layer over the first wiring layer. The semiconductor device includes, as the via cell section of the first hierarchy, a first multiple via cell section (20) having vias (32, 33) for electrically coupling wirings (30, 31) bent in an L-shape of wiring layers adjacent to each other on both sides with the L-shaped bent portion therebetween. The vias of the first multiple via cell section are on a grid line in an X-direction and a grid line in a Y-direction defined with a minimum wiring pitch, and all or part of the vias of the first multiple via cell section are deviated from an intersection of the grid line extending in the X-direction and the grid line in the Y-direction. The circuit cell sections and the via cell sections mean circuit portions constituted in correspondence with cells (defined based on cell data) to be arranged in cell-based wiring design. Thus, the first multiple via cell sections mean circuit portions constituted in correspondence with a first multiple via cell which is one of cell data.

The vias of the first multiple via cell section are placed on each of the grid line in the X-direction and the grid line in the Y-direction, corresponding to the L-shape, so that there is not much difference between spatial conditions in the X-direction and spatial conditions in the Y-direction viewed from the first multiple via cell section. This is different from the case that when a plurality of vias is arranged linearly along a wiring grid, spatial conditions in an arrangement direction are much different from spatial conditions in a direction crossing the arrangement direction. Thus, according to the above means, wirability in the X-direction becomes equivalent to that in the Y-direction. The equivalency in wirability results in the equivalency also in layout restriction points for the different potential vias around the first multiple via cell section in each of the X-direction and the Y-direction, thus reducing the number of vias to which the restriction is applied. Furthermore, the vias of the first multiple via cell section are on grid lines but are deviated from the intersection of the grid lines, so that the cover margins of the vias, that is, the margins allowing deviations of the vias even if the vias are deviated in the wiring directions, substantially increase by the deviations from the intersection, because of relations to the spatial conditions for the surroundings of the vias.

[1_{—}2] The semiconductor device of item 1_{—}1 further includes, as the via cell section of the first hierarchy, a second multiple via cell section (40) having a plurality of vias (43, 44) linearly-arranged for electrically coupling wirings (41, 42) of respective wiring layers adjacent to each other extending linearly with insulating layers therebetween. The respective vias of the second multiple via cell section are on a grid line defined with a minimum wiring pitch, and all or part of the vias of the second multiple via cell section are deviated from an intersection of the grid lines. When the first multiple via cell section cannot be used, also in the case that the second multiple via cell section is used, the cover margins of the vias substantially increase by the deviations from the intersection, because of the relations to the spatial conditions for the surroundings of the vias.

[1_{—}3] when the semiconductor device of item 1_{—}1 further includes a plurality of via cell sections of a second hierarchy for coupling wirings of the second wiring layer to wirings of a third wiring layer, the first multiple via cell section may be adopted as the via cell section of the second hierarchy.

[1_{—}4] When the semiconductor device of item 1_{—}3 further includes a plurality of via cell sections of a third hierarchy for coupling wirings of the third wiring layer to wirings of a fourth wiring layer, the first multiple via cell section may be adopted as the via cell section of the third hierarchy.

[2_{—}1] A semiconductor device has: many circuit cell sections regularly arranged over a semiconductor substrate; terminals of the arranged circuit cell sections formed in a first wiring layer; a plurality of via cell sections of a first hierarchy for coupling the terminals of the circuit cell sections to a second wiring layer over the first wiring layer; and a plurality of via cell sections of a second hierarchy for coupling wirings of the second wiring layer to wirings of a third wiring layer. The semiconductor device includes, as the via cell sections of the first and second hierarchies, a first multiple via cell section including vias for electrically coupling wirings bent in an L-shape of wiring layers adjacent to each other on both sides with the L-shaped bent portion therebetween. The via cell sections of the first hierarchy include the first multiple via cell sections more than the via cell sections of the second hierarchy.

The vias of the first multiple via cell section can be coupled to wirings in the X-direction and wirings in the Y-direction on both sides of the L-shaped bent portion, so that there is not much difference between spatial conditions in the X-direction and spatial conditions in the Y-direction viewed from the first multiple via cell section. This is different from the case that when a plurality of vias is arranged linearly along a wiring grid, spatial conditions in an arrangement direction are much different from spatial conditions in a direction crossing the arrangement direction. Thus, the wirability in the X-direction can be made equivalent to that in the Y-direction. In short, it becomes easy to form other wirings in both of the X-direction and the Y-direction around the first multiple via cell section. Furthermore, the equivalency in wirability around the first multiple via cell section means that it becomes easy to multiplex vias in regions of high wiring density. The wirings of the first wiring layer in which terminals of the circuit cell sections are formed have a higher wiring density than the wirings of other wiring layers. For this reason, by adopting a large number of the first multiple via cell sections with a high priority in such a region, multiplexing of vias is promoted throughout the semiconductor device, thereby contributing to the increase of the yield of the semiconductor device.

[2_{—}2] The semiconductor device of item 2_{—}1 further includes a plurality of via cell sections of a third hierarchy for coupling wirings of the third wiring layer to wirings of a fourth wiring layer. When the semiconductor device includes, as the via cell sections of the third hierarchy, the first multiple via cell sections, the via cell sections of the first hierarchy include the first multiple via cell sections more than the via cell sections of the second hierarchy. It is assumed that the wiring density lowers in the upper layer. In regions of high wiring density, the first multiple via cell section allows multiplexing of vias also in narrow places, and in regions of low wiring density, the first multiple via cell section acts to increase the wiring flexibility in the surrounding regions.

[2_{—}3] The semiconductor device of item 2_{—}2 further includes, as the via cell sections of the first hierarchy, the second multiple via cell sections each having a plurality of vias arranged linearly for electrically coupling wirings of wiring layers adjacent to each other extending linearly with insulating layers therebetween. Even if the first multiple via cell sections L-shaped as the spatial conditions cannot be adopted, adopting linearly-arranged second multiple via cell sections can contribute to the increase of the yield of the semiconductor device.

[2_{—}4] The semiconductor device of item 2_{—}3 further includes, as the via cell sections of the second hierarchy, the second multiple via cell sections. Also for the via cell sections of the second hierarchy, the same thing as item 2_{—}2 can be applied.

[2_{—}5] The semiconductor device of item 2_{—}4 further includes, as the via cell sections of the third hierarchy, the second multiple via cell sections. Also for the via cell sections of the third hierarchy, the same thing as item 2_{—}2 can be applied.

[2_{—}6] Each of the vias is formed by filling a conductive via plug coupled to wirings of the respective upper and lower wiring layers into a via hole penetrating an insulating layer between the upper and lower wiring layers.

[3_{—}1] A wiring method for a semiconductor device includes the process of, when using a computer to arrange circuit cells necessary for constituting required circuits and then to couple wiring patterns to the arranged circuit cells, arranging a first multiple via cell including vias for electrically coupling wiring patterns bent in an L-shape of different wiring layers on both sides with the L-shaped bent portion therebetween, at points for coupling wiring patterns of different wiring layers. According to this method, each of the first multiple via cell sections has a plurality of vias, so that when the first multiple via cells are used, the time of the wiring processing can be reduced as compared with data processing of adding and-multiplexing vias around specific vias in the wiring processing.

[3_{—}2] In the wiring method of item 3_{—}1, when the first multiple via cell is arranged, the vias of the first multiple via cell section are placed on a grid line in an X-direction and a grid line in a Y-direction defined with a minimum wiring pitch, and all or part of the vias of the first multiple via cell section are deviated from an intersection of the grid line in the X-direction and the grid line in the Y-direction. Line segments coupling centers of vias constituting the first multiple via cell to each other are slanted against the grid line in the X-direction and the grid line in the Y-direction, and the distance between the centers has been previously defined, so that the above operation can be performed. It is not required that vias are arranged at the intersection of grid lines. Each of the vias only has to be placed on a grid line.

According to the above description, the vias of the first multiple via cell section are placed on each of the grid line in the X-direction and the grid line extending in the Y-direction, corresponding to the L-shape, so that there is not much difference between spatial conditions in the X-direction and spatial conditions in the Y-direction viewed from the first multiple via cell section. This is different from the case that when the vias are arranged linearly along a wiring grid, spatial conditions in an arrangement direction are much different from spatial conditions in a direction crossing the arrangement direction. Thus, the wirability in the X-direction becomes equivalent to that in the Y-direction. The equivalency in wirability results in the equivalency also in layout restriction points for the different potential vias around the first multiple via cell section in each of the X-direction and the Y-direction, thus reducing the number of vias to which the restriction is applied. Furthermore, the vias of the first multiple via cell section are on grid lines but are deviated from the intersection of the grid lines, so that the cover margins of the vias, that is, the margins allowing deviations of the vias even if the vias are deviated in the wiring directions, substantially increase by the deviations from the intersection, because of relations to the spatial conditions for the surroundings of the vias. This can contribute to the high integration of a semiconductor device.

[3_{—}3] The wiring method of item 3_{—}2 performs the following processing as one concrete processing when using a computer to arrange circuit cells necessary for constituting required circuits and then to couple wiring patterns to the arranged circuit cells. The concrete processing includes the processes of: reading data of the first multiple via cell including the vias for electrically coupling wiring patterns bent in an L-shape of different wiring layers on both sides with the L-shaped bent portion therebetween; and arranging the first multiple via cell using the data at points for coupling wiring patterns of different wiring layers.

It is also possible to use first multiple via cells at all connection points between wiring layers from the start. In this case, the effect of increase of the yield can be expected most, but high integration of the semiconductor device is sacrificed to some extent.

[3_{—}4] <<Single Via Cells are Selectively Replaced with First Multiple Via Cells>>

The wiring method of item 3_{—}2 performs the following processing as another concrete processing when using a computer to arrange circuit cells necessary for constituting required circuits and then to couple wiring patterns to the arranged circuit cells. The concrete processing includes the processes of: reading data of the first multiple via cell including the vias for electrically coupling wiring patterns bent in an L-shape of different wiring layers on both sides with the L-shaped bent portion therebetween; reading data of single via cells for electrically coupling wiring patterns of different wiring layers using single vias; arranging the single via cells using the data at points for coupling wiring patterns of different wiring layers; determining whether or not a spatial conditions necessary for replacing the single via cells with first multiple via cells is satisfied around the arranged single via cells; and rearranging the first multiple via cells using the data instead of single via cells at points determined to satisfy the spatial conditions.

As a result, at first, single via cells are used at connection points between wiring layers, so that vias for coupling the lowest wiring layer of high wiring density including wiring patterns in circuit cells to the upper wiring layer can be initially arranged at a high density, and in this point, the highest priority may be given to a request for high integration of the semiconductor device. In this condition, replacing the single via cells with first multiple via cells within a possible range can contribute to the increase of the yield of the semiconductor device.

[3_{—}5] <<Single Via Cells are Forcibly Replaced with First Multiplex Via Cells>>

The wiring method of item 3_{—}2 performs the following processing as another concrete processing when using a computer to arrange circuit cells necessary for constituting required circuits and then to couple wiring patterns to the arranged circuit cells. The concrete processing includes the processes of: reading data of the first multiple via cell including the vias for electrically coupling wiring patterns bent in an L-shape of different wiring layers on both sides with the L-shaped bent portion therebetween; reading data of single via cells for electrically coupling wiring patterns of different wiring layers using single vias; arranging the single via cells using the data at points for coupling wiring patterns of different wiring layers; rearranging the first multiple via cells using the data instead of the arranged single via cells; and allowing wiring patters around the first multiple via cells to satisfy the spatial conditions when the rearranged first multiple via cells do not satisfy the spatial conditions between the first multiple via cells and the surroundings.

As a result, at first, single via cells are used at connection points between wiring layers, so that vias for coupling the lowest wiring layer of high wiring density including wiring patterns in circuit cells to the upper wiring layer can be initially arranged at a high density, and in this point, the highest priority may be given to a request for high integration of the semiconductor device. In this condition, forcibly replacing the single via cells with first multiple via cells can achieve the increase of the yield of the semiconductor device more than the means of item 3_{—}4. However, time for correcting the wiring patterns is needed.

[3_{—}6] <<Single Via Cells are Selectively Replaced with Second Multiple Via Cells, and Single Via Cells Which Cannot be Replaced with Second Multiple Via Cells are Forcibly Replaced with First Multiple Via Cells>>

The wiring method of item 3_{—}2 performs the following processing as still another concrete processing when using a computer to arrange circuit cells necessary for constituting required circuits and then to couple wiring patterns to the arranged circuit cells. The concrete processing includes the processes of: reading data of the first multiple via cell including the vias for electrically coupling wiring patterns bent in an L-shape of different wiring layers on both sides with the L-shaped bent portion therebetween; reading data of second multiple via cells for electrically coupling wiring patterns of different wiring layers extending linearly using a plurality of vias arranged linearly in parallel; reading data of single via cells for electrically coupling wiring patterns of different wiring layers using single vias; arranging the single via cells using the data at points for coupling wiring patterns of different wiring layers; determining whether or not a spatial conditions necessary for replacing the single via cells with second multiple via cells is satisfied around the arranged single via cells; rearranging the second multiple via cells using the data instead of single via cells at points determined to satisfy the spatial conditions; rearranging the first multiple via cells using the data instead of single via cells at points determined not to satisfy the spatial conditions; and allowing wiring patters around the first multiple via cells to satisfy the spatial conditions when the rearranged first multiple via cells do not satisfy the spatial conditions between the first multiple via cells and the surroundings.

As a result, at first, single via cells are used at connection points between wiring layers, so that vias for coupling the lowest wiring layer of high wiring density including wiring patterns in circuit cells to the upper wiring layer can be initially arranged at a high density, and in this point, the highest priority may be given to a request for high integration of the semiconductor device. In this condition, replacing single via cells with second multiple via cells within a possible range and forcibly replacing the remaining single via cells with first multiple via cells can achieve the increase of the yield of the semiconductor device more than the means of item 3_{—}4. However, time for correcting the wiring patterns is needed but less than that in item 3_{—}5.

[3_{—}7] <<Single Via Cells are Selectively Replaced with First Multiple Via Cells, and Single Via Cells Which Cannot be Replaced with First Multiple Via Cells are Forcibly Replaced with Second Multiple Via Cells>>

The wiring method of item 3_{—}2 performs the following processing as still another concrete processing when using a computer to arrange circuit cells necessary for constituting required circuits and then to couple wiring patterns to the arranged circuit cells. The concrete processing includes the processes of: reading data of the first multiple via cell including the vias for electrically coupling wiring patterns bent in an L-shape of different wiring layers on both sides with the L-shaped bent portion therebetween; reading data of second multiple via cells for electrically coupling wiring patterns of different wiring layers extending linearly using a plurality of vias arranged linearly in parallel; reading data of single via cells for electrically coupling wiring patterns of different wiring layers using single vias; arranging the single via cells using the data at points for coupling wiring patterns of different wiring layers; determining whether or not a spatial conditions necessary for replacing the single via cells with first multiple via cells is satisfied around the arranged single via cells; rearranging the first multiple via cells using the data instead of single via cells at points determined to satisfy the spatial conditions; rearranging the second multiple via cells using the data instead of single via cells at points determined not to satisfy the spatial conditions; and allowing wiring patters around the second multiple via cells to satisfy the spatial conditions when the rearranged second multiple via cells do not satisfy the spatial conditions between the second multiple via cells and the surroundings.

As a result, at first, single via cells are used at connection points between wiring layers, so that vias for coupling the lowest wiring layer of high wiring density including wiring patterns in circuit cells to the upper wiring layer can be initially arranged at a high density, and in this point, the highest priority may be given to a request for high integration of the semiconductor device. In this condition, replacing single via cells with first multiple via cells within a possible range and forcibly replacing the remaining single via cells with second multiple via cells can achieve the increase of the yield of the semiconductor device more than the means of item 3_{—}4. However, time for correcting the wiring patterns is needed but less than that in item 3_{—}6, because, as described above, in regions of high wiring density, first multiple via cells enables multiplexing of vias also in narrow places, and in regions of low wiring density, first multiple via cells act to increase the wiring flexibility in the surrounding regions, so that the number of single via cells which cannot be replaced with the first multiple via cells and are remained is reduced and consequently the correction points of wiring patterns caused by forcibly replacing the single via cells with the second multiple via cells are reduced.

[4_{—}1] A data processing system supporting wiring design for a semiconductor device includes a data processor executing a program and a storage device. The data processor, when arranging circuit cells necessary for constituting required circuits and then coupling wiring patterns to the arranged circuit cells, performs the process of arranging first multiple via cells including vias for electrically coupling wiring patterns bent in an L-shape of different wiring layers on both sides with the L-shaped bent portion therebetween, at points for coupling wiring patterns of different wiring layers. According to this processing, each of the first multiple via cells has the vias, so that when the first multiple via cells are used, the time of the wiring processing can be reduced as compared with data processing of adding and multiplexing vias around specific vias in the wiring processing.

[4_{—}2] In the data processing system of item 4_{—}1, when the first multiple via cells are arranged, the vias of the first multiple via cell sections are placed on a grid line in an X-direction and a grid line in a Y-direction defined with a minimum wiring pitch, and all or part of the vias of the first multiple via cell section are deviated from an intersection of the grid line in the X-direction and the grid line in the Y-direction. Thus, the wirability in the X-direction becomes equivalent to that in the Y-direction. The equivalency in wirability results in the equivalency also in layout restriction points for the different potential vias around the first multiple via cell section in each of the X-direction and the Y-direction, thus reducing the number of vias to which the restriction is applied. Furthermore, the vias of the first multiple via cell section are on grid lines but are deviated from the intersection of the grid lines, so that the cover margins of the vias, that is, the margins allowing deviations of the vias even if the vias are deviated in the wiring directions, substantially increase by the deviations from the intersection, because of relations to the spatial conditions for the surroundings of the vias. This can contribute to high integration of a semiconductor device.

[4_{—}3] In the data processing system of item 4_{—}2, the data processor may performs processing of item 3_{—}3, item 3_{—}4, item 3_{—}5, item 3_{—}6, or item 3_{—}7, when arranging circuit cells necessary for constituting required circuits and coupling wiring patterns to the arranged circuit cells.

### 2. Details of Embodiments

The embodiments will be described in more detail.

<<Semiconductor Device>>

FIG. 2 illustrates circuit cells disposed in a semiconductor device. A semiconductor device 1 is formed over but not limited to a semiconductor substrate such as a single-crystal silicon substrate by a complementary MOS integrated circuit manufacturing technique. Many circuit cell sections are arranged over the semiconductor substrate. A NAND gate cell section 2, an inverter cell section 3, and an OR gate cell section 4 are shown as typical examples of the circuit cell sections. The signal terminals Ts of the circuit cell sections are coupled by signal wirings SL to form required logics. The power terminals Tp of the circuit cell sections 2, 3, and 4 are coupled to a power wiring VL and a ground wiring GL.

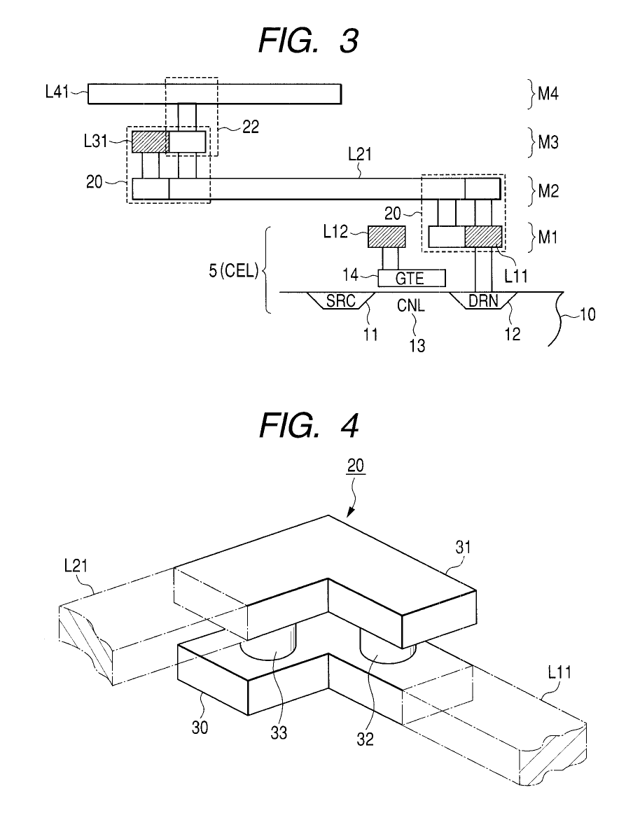

FIG. 3 roughly illustrates the longitudinal section structure of the semiconductor device 1. The reference numeral 5 typically denotes a MOS transistor constituting a circuit cell section (CEL). In an impurity diffusion region 10 formed in the semiconductor substrate, a source electrode (SRC) 11 and a drain electrode (DRN) 12 are formed into a conduction type which is different from the impurity diffusion region. An impurity diffusion region between the source electrode 11 and the drain electrode 12 is formed to be a channel-forming region (CNL) 13 over which a gate electrode (GTE) 14 is formed through a gate insulating film. In FIG. 3, a first wiring layer M1, a second wiring layer M2, a third wiring layer M3, and a fourth wiring layer M4 are shown as examples of wiring layers. Interlayer insulating films are provided between wiring layers, in which metal wirings such as the signal wirings and the power system wirings are formed.

The circuit cell section (CEL) 5 is a circuit portion specified by circuit cell data used for a cell-based layout design (wiring design), and terminals T such as the signal terminals and the power system terminals of the circuit cell section (CEL) 5 are allocated as wirings L11 and L12 of the first wiring layer M1. Shapes of wirings in circuit portions defined by circuit cell data do not become objects of changes in principle in the layout design. Thus, the wiring patterns of the wirings L11 and L12 which are terminals of the cell are not objects of shape changes in the layout design.

For the wirings SL, VL, and GL for coupling the terminals of the circuit cell, wirings of the wiring layers M2, M3, and M4 over the wiring layer M1 are used. Wirings of wiring layers which are different from one another are coupled by via cell sections. FIG. 3 illustrates a first multiple via cell section 20 as a via cell section of a first hierarchy coupling the wiring L11 of the wiring layer M1 to the wiring L21 of the wiring layer M2, another first multiple via cell section 20 as a via cell section of a second hierarchy coupling the wiring L21 of the wiring layer M2 to the wiring L31 of the wiring layer M3, and a single via cell section 22 as a via cell section of a third hierarchy coupling the wiring L31 of the wiring layer M3 to the wiring L41 of the wiring layer M4.

FIG. 4 illustrates the structure of the first multiple via cell section 20 coupling the wiring L11 of the wiring layer M1 to the wiring L21 of the wiring layer M2 in FIG. 3. The first multiple via cell section 20 includes a plurality of vias 32 and 33 for electrically coupling a wiring 30 bent in an L-shape of the wiring layer M1 to a wiring 31 bent in an L-shape of the wiring layer M2 adjacent to the wiring 30, on both sides of the first multiple via cell section 20 with the L-shaped bent portion therebetween. Each of the vias is formed by a conductive via plug coupled to respective wirings of the upper and lower wiring layers being filled into a via hole penetrating an insulating layer between the upper and lower wiring layers. FIG. 4 represents the shapes of the cross sections of the vias with rectangular shape. However, the shapes may be circles or ellipses and there is no restriction on the shapes.

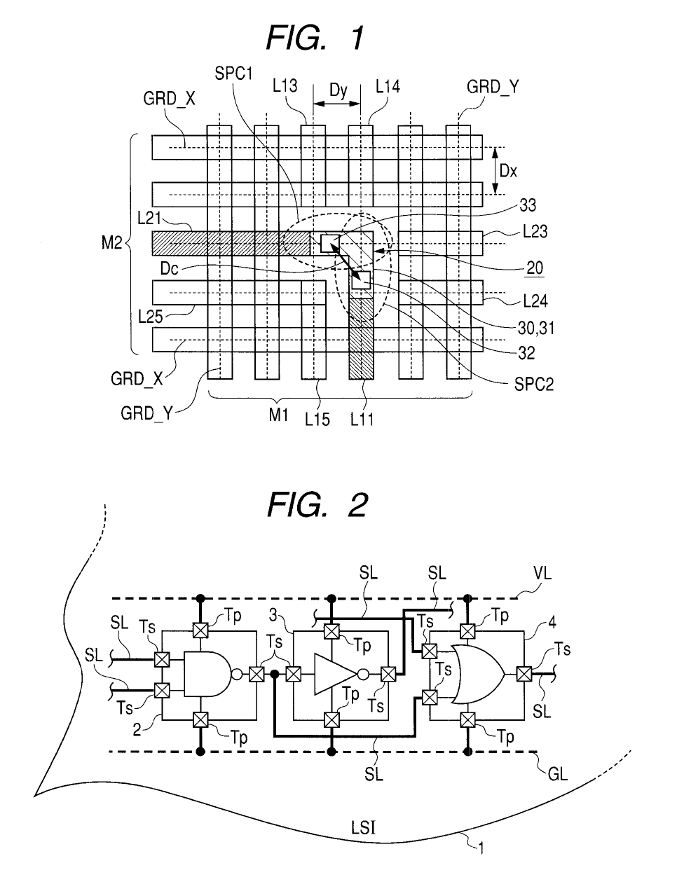

FIG. 1 illustrates a planar structure of the first multiple via cell section 20. The wirings of the wiring layer M1 extend longitudinally and the wirings of the wiring layer M2 extend transversely. The minimum wiring width of the wiring layers is set to, for example, 140 nanometers (nm), and the minimum interval of the wirings is set to, for example, 140 nm. In this wiring rule, the layout of the wirings of the wiring layers M1 and M2 is designed so that the center lines of the wirings are on the grid lines GRD_X with the wiring pitch Dx of 280 nm and the grid lines GRD_Y with the wiring pitch Dy of 280 nm. By this rule, the design value of the distance Dc between the centers of the vias 32 and 33 of the first multiple via cell section 20 is set to 280 nm. At that time, the vias of the first multiple via cell section are on a grid line GRD_X in the X-direction or on a grid line GRD_Y in the Y-direction and are deviated from an intersection of the grid line GRD_X in the X-direction and the grid line GRD_Y in the Y-direction.

The vias of the first multiple via cell section 20 are placed on each of the grid line GRD_X in the X-direction and the grid line GRD_Y in the Y-direction, corresponding to the L-shape, so that there is not much difference between the spatial conditions in the X-direction and the spatial conditions in the Y-direction viewed from the first multiple via cell section 20. In other words, the ends of the wirings L13, L14, and L15 of the first wiring layer M1 are separated from the wiring 30 of the first multiple via cell section 20 so as to keep the minimum wiring interval therebetween. The ends of the wirings L23, L24, and L25 of the second wiring layer M2 are separated from the wiring 31 of the first multiple via cell section 20 to keep the minimum wiring interval therebetween. Thus, the size of space SPC1 left for the wirings of first wiring layer M1 with respect to the first multiple via cell section 20 is substantially equal to the size of space SPC2 left for the wirings of second wiring layer M2 with respect to the first multiple via cell section 20.

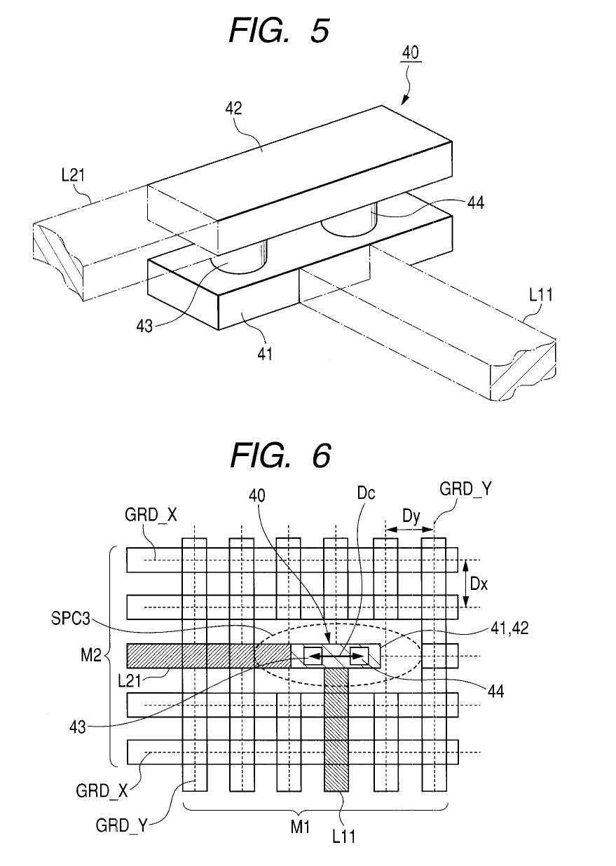

FIG. 5 illustrates the structure of a second multiple via cell section 40 which is another example of a multiple via cell section. The second multiple via cell section 40 is configured to have a plurality of vias 43 and 44 provided linearly which are used for electrically coupling wirings 41 and 42 of the wiring layers M1 and M2 adjacent to each other and extending linearly.

When the second multiple via cell section 40 in which vias are arranged in series along a wiring grid is adopted as illustrated in FIG. 6 for the first multiple via cell section 20 in FIG. 1, the spatial conditions in the X-direction which is the arrangement direction of the vias is much different from the spatial conditions in the Y-direction crossing the X-direction. For example, in the space SPC3, a space which must be separated from the wirings of the wiring layer M1 must be larger than a space which must be separated from the wirings of the wiring layer M2. Thus, in the case that the first multiple via cell section 20 in the L-shape illustrated in FIG. 1 is adopted, the wirability in the X-direction becomes equivalent to that in the Y-direction more than in the case that the second via cell section 40 is adopted.

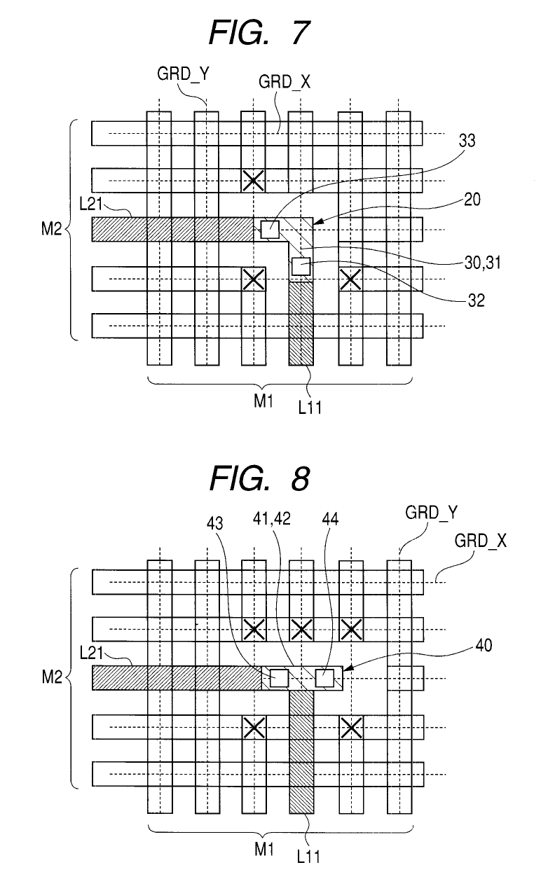

FIG. 7 shows layout restriction points for different potential vias around the first multiple via cell section 20. A design distance between the different potential vias connected to different potential signal lines must be set larger than the minimum pitch of the same potential vias. Alignment errors of wiring masks of two layers which are different in the distance between centers of vias are accumulated in a manufacturing process, so that, for example, different potential vias must be separated by twice or more the minimum wiring pitch. According to this restriction, the mark X is attached to the layout restriction points of the different potential vias around the first multiple via cell section 20. In this case, as illustrated in FIG. 1, the equivalency in wirability in each of the X-direction and the Y-direction around the first multiple via cell section 20 results in the equivalency also in layout restriction points for the different potential vias around the first multiple via cell section 20 in each of the X-direction and the Y-direction, thus reducing the number of vias to which the restriction is applied. As a comparative example, FIG. 8 shows layout restriction points of different potential vias around the second multiple via cell section 40. Wirable spaces around the second multiple via cell section 40 are not equalized as compared with those around the first multiple via cell section 20, so that the number of layout restriction points over the grid lines GRD_Y is larger than that of layout restriction points on the grid lines GRD_X. As is clear from FIGS. 7 and 8, if the layout restriction of different potential vias is equalized in each of the X-direction and the Y-direction, the number of layout restriction points of different potential vias is reduced, thereby contributing to high integration of a semiconductor device.

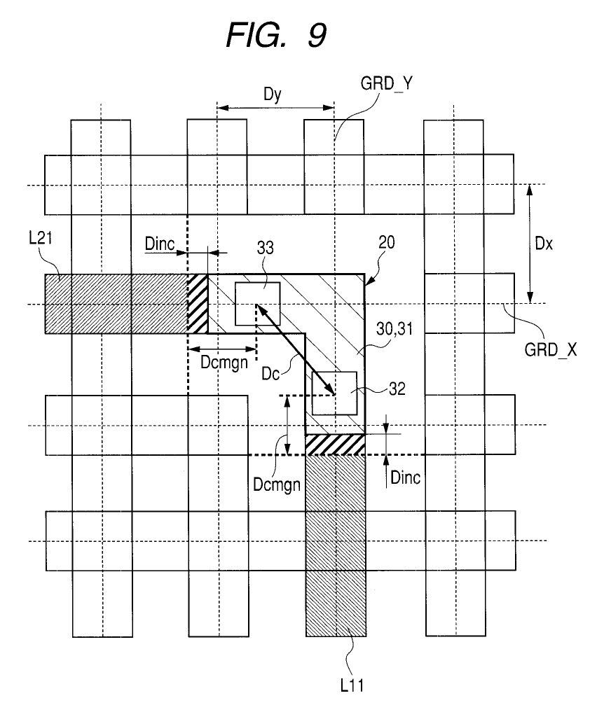

FIG. 9 illustrates cover margins of respective vias in the first multiple via cell section 20. Vias 32 and 33 of the first multiple via cell section 20 are on the grid lines GRD_X and GRD_Y but are deviated from the intersection of the grid, so that cover margins Dcmgn of the vias 32 and 33, that is, a margin allowing a deviation of the via 32 even if the via 32 is deviated in the direction of the grid line GRD_Y and a margin allowing a deviation of the via 33 even if the via 33 is deviated in the direction of the grid line GRD_X, substantially increase by the deviation Dinc, because of the relations to the spatial conditions (minimum pitch) for the surroundings of the vias. This contributes to the increase of the yield of the semiconductor device. This substantial increase of the cover margins is also applicable to the second multiple via cell section 40.

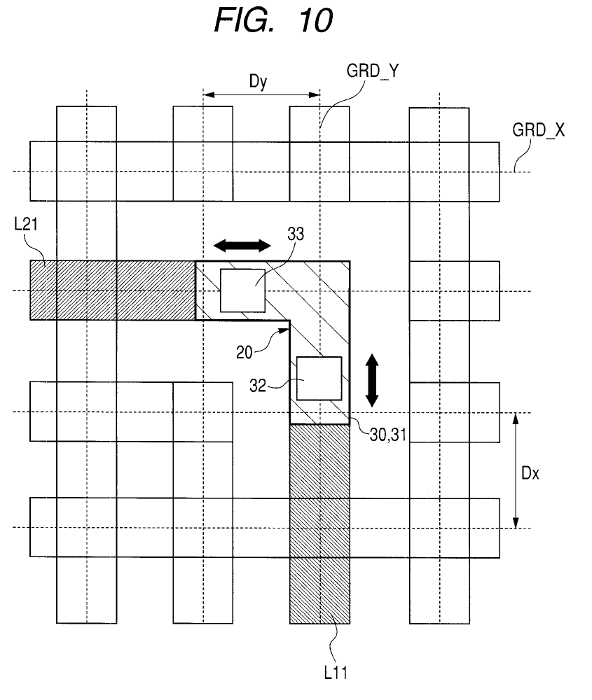

FIG. 10 illustrates an entire cover margin of vias in a first multiple via cell section. When wiring masks of the upper and lower layers have been deviated along a grid line GRD_X, an overlap between a via 32 and wiring layers L11 and L12 is not maintained well, while an overlap between a via 33 and wiring layers L11 and L12 is maintained well. When wiring masks of the upper and lower layers have been deviated along a grid line GRD_Y, in contrast to the above, the overlap between the via 32 and the wiring layers L11 and L12 is maintained well, while the overlap between the via 33 and the wiring layers L11 and L12 is not maintained well. However, in any case, at least one of the vias 32 and 33 overlaps the wiring layers L11 and L12 to achieve an electrically good connection state, because the first multiple via cell section 20 is structured so as to be coupled to a wiring in the X-direction and a wiring in the Y-direction at both sides of the L-shaped bent portion. In the case of the second multiple via cell section 40 illustrated in FIG. 8, if the wiring masks of the upper and lower layers are much deviated along the grid line GRD_X, there may be a case that the connections between the vias and the wirings cannot be satisfied.

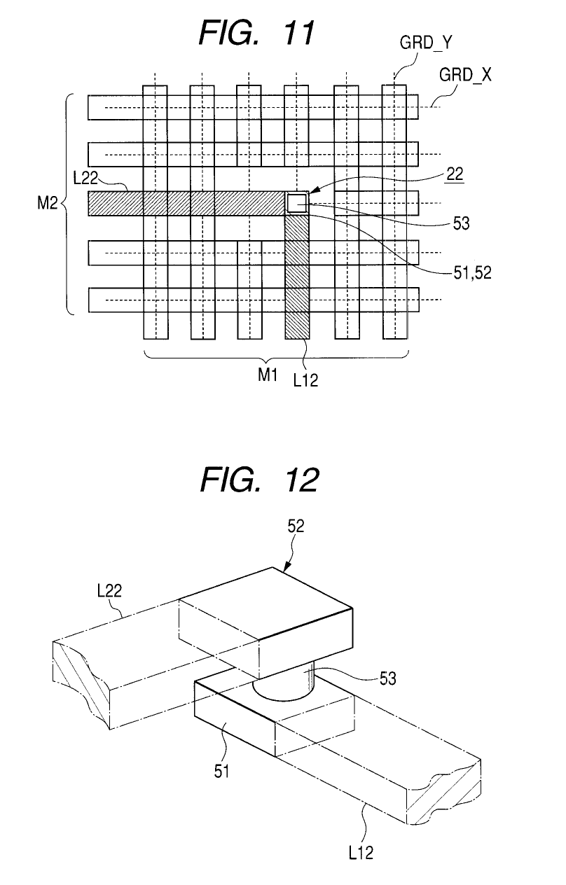

FIG. 11 illustrates the planar structure of a single via cell section 22, and FIG. 12 is a perspective view thereof. These figures show the single via cell section 22 for a connection between wiring layers M1 and M2 as an example. The single via cell section 22 has a via 53 for electrically coupling the wirings 51 and 52 of different wiring layers M1 and M2.

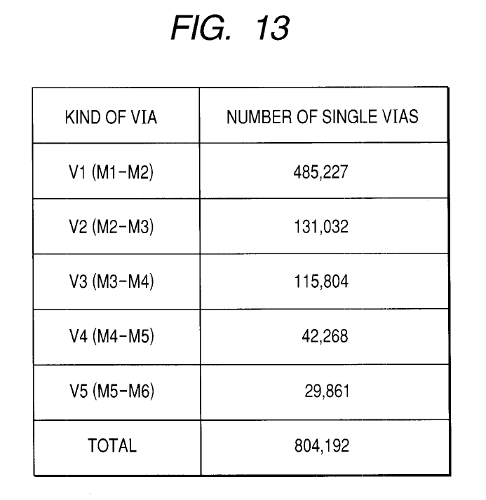

FIG. 13 illustrates the number distribution of single via cell sections between different wiring layers in the case that the wirings of the wiring layers are coupled to each other at the single via cell sections. As shown in FIG. 13, the number of single via cell sections of the first hierarchy V1 between the wiring layer M1 and the wiring layer M2 is overwhelmingly large, and the number of single via cell sections decreases as the hierarchy increases. As illustrated in FIG. 3, many cell terminals of the circuit cell section (CEL) 5 are arranged in the first wiring layer M1. Many cell terminals arranged in the circuit cell section are coupled to each other through wirings in order to realize required logics, because via cell sections for coupling the cell terminals to wirings of the second wiring layer M2 are arranged at a high density in the first hierarchy V1. Thus, the wirings of the first wiring layer M1 in which the terminals of the circuit cell section are formed are provided at a higher density than the wirings of the other wiring layers. For this reason, adopting a large number of first multiple via cell sections having surrounding wirable regions little unbalanced in the X-direction and the Y-direction, makes it possible to promote multiplexing of vias throughout the semiconductor device and to further increase the yield of the semiconductor device. In regions of high wiring density, first multiple via cell sections 20 allow multiplexing of vias also in a narrow place, and in regions of low wiring density, first multiple via cell sections 20 increase the wiring flexibility in the surrounding regions. Even if first multiple via cell sections 20 in the L-shape cannot be adopted in terms of the spatial conditions, the yield of the semiconductor device can be increased by adopting linearly-arranged second multiple via cell sections 40.

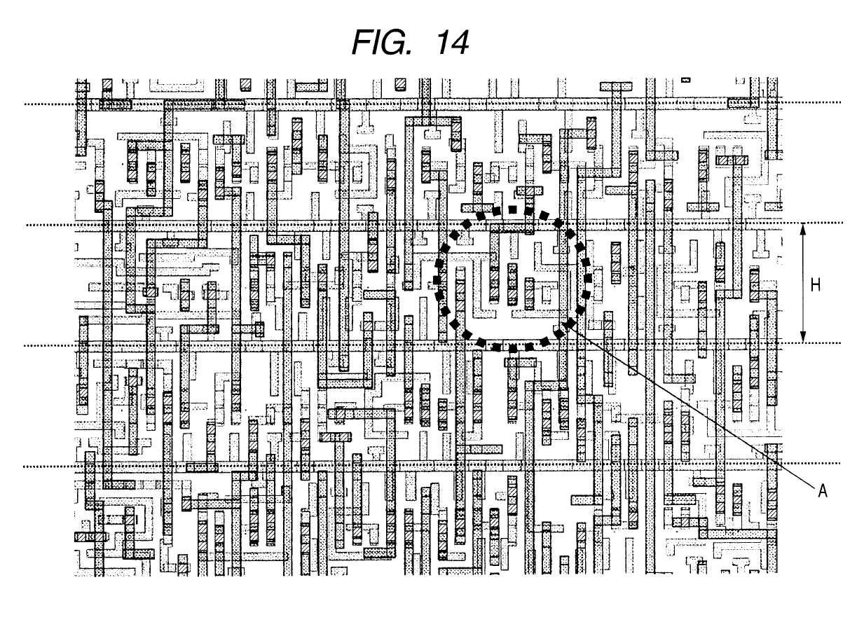

FIG. 14 illustrates a concrete planar layout of wirings of the wiring layers M1 and M2. H denotes cell height of a circuit cell section.

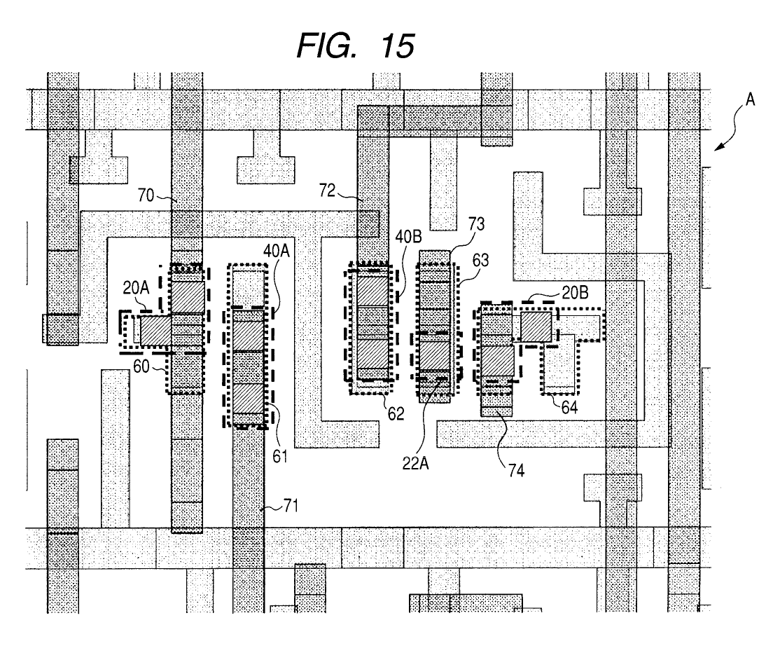

FIG. 15 illustrates the details of the part A in FIG. 14. In FIG. 15, the reference numerals 60 to 64 denote cell terminals of the circuit cell section (CEL) 5, which are formed by wirings of the first wiring layer M1. The reference numeral 20A denotes a first multiple via cell section coupling the cell terminal 60 to the wiring 70 of the wiring layer M2. The reference numeral 40A denotes a second multiple via cell section coupling the cell terminal 61 to the wiring 71 of the wiring layer M2. The reference numeral 40B denotes a second multiple via cell section coupling the cell terminal 62 to the wiring 72 of the wiring layer M2. The reference numeral 22A denotes a single via cell section coupling the cell terminal 63 to the wiring 73 of the wiring layer M2. The reference numeral 20B denotes a first multiple via cell section coupling the cell terminal 64 to the wiring 74 of the wiring layer M2.

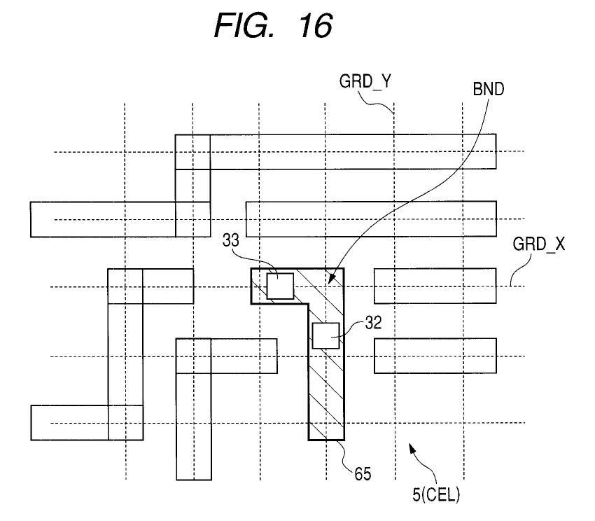

FIG. 16 illustrates how to easily couple cell terminals of a circuit cell section to a first multiple via cell section. When the cell terminal 65 of the circuit cell section (CEL) 5 has an L-shaped bent portion, it is desirable that the center BND of the bent portion is positioned at the intersection of a grid line GRD_X in the X-direction and a grid line GRD_Y in the Y-direction. As a result, there is an advantage that when the cell terminal is connected at the first multiple via cell section 20, the vias 32 and 33 can be easily deviated from the intersection of the grid lines GRD_X and GRD_Y. In a layout processing of the first multiple via cell section 20, only the operation of positioning the center BND of the bent portion at the intersection of required grid lines GRD_X and GRD_Y is needed.

<<Data Processing System>>

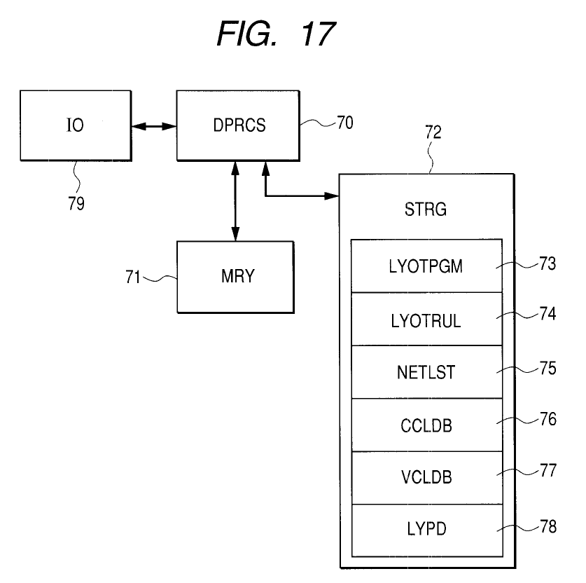

FIG. 17 illustrates a data processing system supporting wiring design for a semiconductor device. The data processing system has a data processor (DPRCS) 70 executing a program, a memory (MRY) 71 as a storage device, and an input/output circuit (IO) 79 such as a pointing device and a display. Into the memory 71, programs and data stored in an auxiliary storage device (STRG) 72 are loaded. The auxiliary storage device 72 has regions storing a layout processing program (LYOTPGM) 73 for performing data processing which supports cell-based wiring design for the semiconductor device, layout rule data (LYOTRUL) 74 having various layout rules used for wiring processing, a net list (NETLST) 75 defining the relation of circuit connection of the semiconductor device, a circuit cell database (CCLDB) 76 having verified various kinds of circuit cell data constituting basic circuits such as gate circuits, flip-flop circuits, and computing units, a via cell database (VCLDB) 77 having various kinds of via cell data, and pattern data (LYPD: layer pattern information) 78 for each of wiring layers obtained one by one by layout and wiring.

The circuit cell database 76 has the names of circuit cells and pattern graphic data constituting the circuit cells.

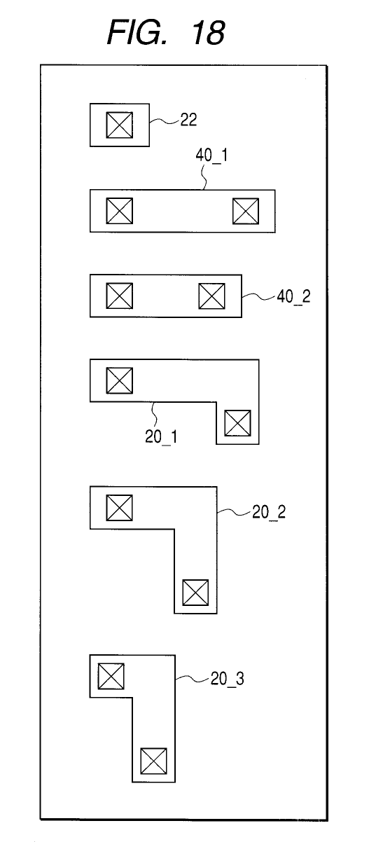

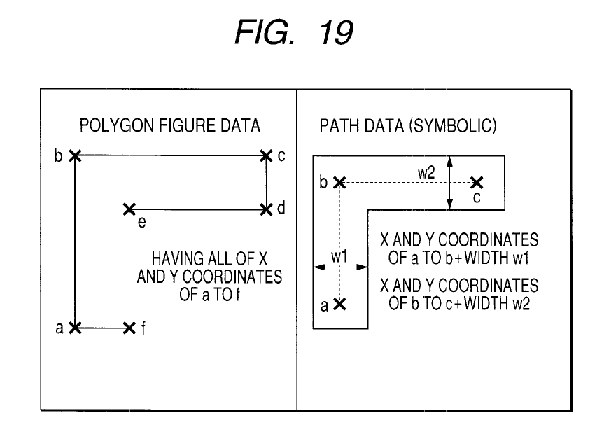

The via cell database 77 has the names of via cells and pattern graphic data constituting the via cells. For example, as illustrated in FIG. 18, the via cell database 77 has data constituting first multiple via cell sections 20, second multiple via cell sections 40, and a single via cell section 22, which are different in size and distance between vias. In this specification, a via cell section means a physical configuration, and when the via cell section is abstractly grasped in wiring processing or the like, the via cell section is simply referred to as a via cell and defined as an object grasped by via cell data.

Graphic data of circuit cells and via cells and graphic data of examples and pattern information have, for example, a data structure of polygon data or path data (symbolic data) shown in FIG. 19. The polygon data identifies the graphic pattern by the x and y coordinate data of the vertexes of the polygon. The polygon may be broken down into quadrangles to obtain the coordinate data of the quadrangles. The path data identifies the graphic pattern by the x and y coordinate data of the center line and width data in directions orthogonal to the center line. In the processing using the path data, edge processing of the rectangular is performed using the width data at coordinates of the center line. The coordinates of the graphic data are the local coordinates in each of the circuit cell database 76 and the via cell database 77, and the global coordinates of the semiconductor device in the layer pattern information 78.

The layout processing program 73 is executed by the data processor 70 to control the following wiring method for a semiconductor device.

<<Wiring method>>

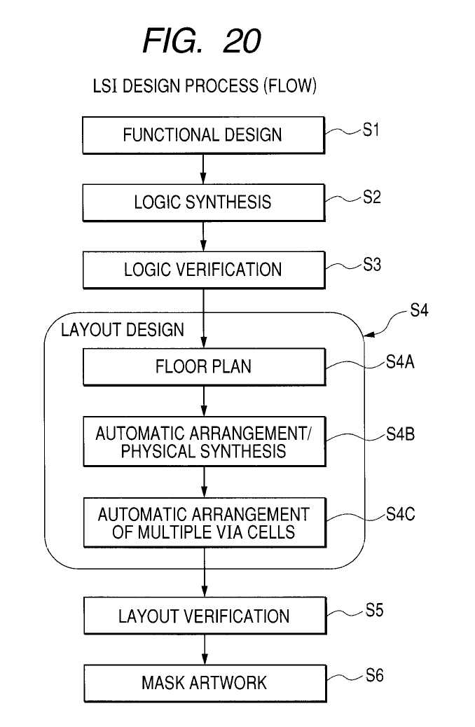

FIG. 20 shows the position of wiring design in the design processing of a semiconductor device. The design of a semiconductor device includes functional design (S1) using function description language such as HDL, logic synthesis (S2) constituting gate level logics using data described by HDL or the like, logic verification (S3) by logic simulation or the like to the result of the logic synthesis, cell-based wiring (layout) design (S4), layout verification (S5) to the result of the wiring design, and mask artwork (S6) designing a pattern on the basis of the layout data.

In the layout design S4, layout and wiring are performed on a cell basis. For example, the layout design S4 includes floor plan creation processing (S4A), automatic layout of circuit cells and physical pattern generation processing (S4B) corresponding thereto, and the subsequent automatic layout processing of multiple via cells (S4C). Here, in the automatic layout of circuit cells and physical pattern generation processing (S4B) corresponding to the layout, single via cells are used for connections between wirings of different wiring layers. In the processing S4C, the processing of replacing single via cells with multiple via cells is performed. When the automatic layout processing of multiple via cells S4C has come to cause wirings short-circuited or layout rule violation such as wiring pitch violation, the processing of correcting physical patterns is performed.

<<Single Via Cells are Selectively Replaced with First Multiple Via Cells>>

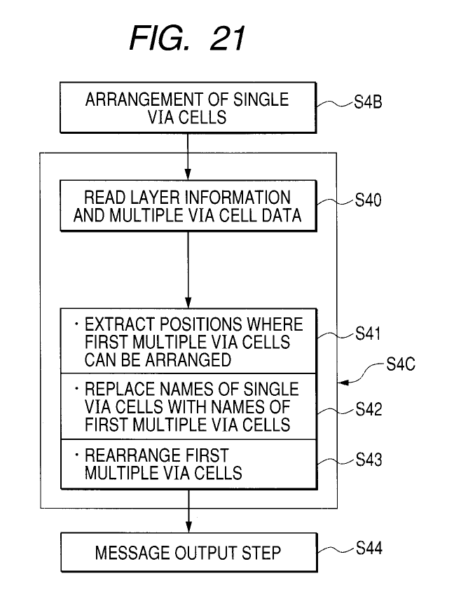

FIG. 21 shows a concrete example of the processing of automatic layout processing of multiple via cells S4C. In the processing of S4B, single via cells are used for coupling wirings of different wiring layers, and the result of the processing of S4B is stored in the auxiliary storage device 72 as layer information for each of the wiring layers. At automatic layout of multiple via cells, the data processor 70 reads layer information including the locations of single via cells and the graphic data of wiring patterns around the single via cells from the auxiliary storage device 72, and at the same time, reads cell data 77 of multiple via cells from the auxiliary storage device 72 (S40). The data processor 70 extracts points where single via cells can be replaced with first multiple via cells on the basis of the read information. In other words, the data processor 70 determines whether the spatial conditions necessary to replace single via cells at the points with first multiple via cells are satisfied around the single via cells (S41). The spatial conditions include a condition that the wiring is not short-circuited with any other wiring, a condition that the minimum interval is kept between the wiring and any other wiring, a condition that a sufficient interval is kept between the vias and adjacent different potential vias, and the like. When the spatial conditions are satisfied, the cell names of corresponding single via cells are changed to cell names of first multiple via cells (S42), and patterns are generated so as to rearrange first multiple via cells at the positions of the single via cells using the cell data of the first multiple via cells (S43). The data processor 70 performs the above processing for all of single via cells at extracted locations. When finishing the processing, the data processor 70 outputs a message of the effect (S44).

Since first multiple via cells each have a plurality of vias 32 and 33, when the first multiple via cells are used, the time of the wiring processing can be reduced as compared with data processing of multiplexing single vias by adding other single vias around specific single vias in the wiring processing.

Furthermore, at first, single via cells are used at connection points between wiring layers, so that vias for coupling the lowest wiring layer of high wiring density including wiring patterns in circuit cells to the upper wiring layer can be initially arranged at a high density, and in this point, the highest priority may be given to a request for high integration of the semiconductor device. In this condition, replacing single via cells with first multiple via cells within a possible range can contribute to increase of the yield of the semiconductor device.

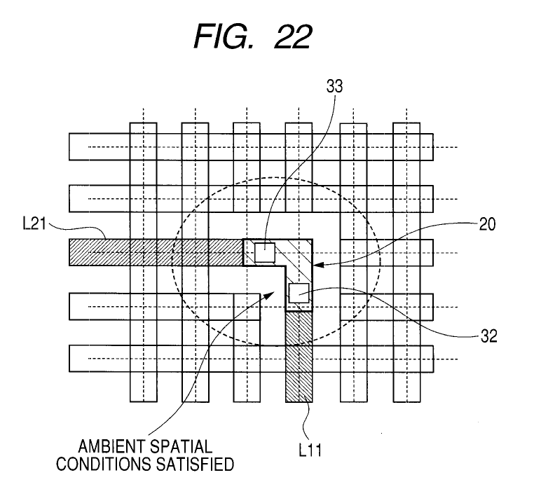

When the processing of FIG. 21 is performed, the first multiple via cells obtained by the replacement satisfy the spatial conditions to the surroundings as shown in FIG. 22.

<<Single Via Cells are Forcibly Replaced with First Multiple Via Cells>>

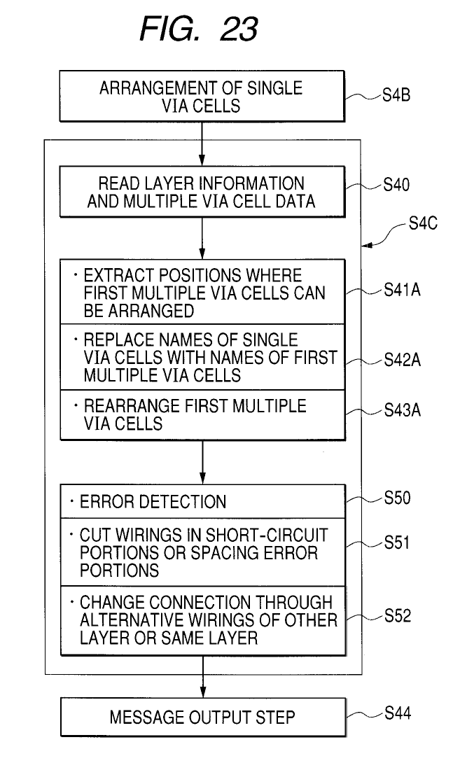

FIG. 23 shows another concrete example of the processing of automatic layout of multiple via cells S4C. In the processing of S4B, single via cells are used for coupling wirings of different wiring layers, and the result of the processing of S4B is stored in the auxiliary storage device 72 as the layer information 78 for each of the wiring layers. At automatic layout of multiple via cells, the data processor 70 reads layer information including the locations of single via cells and the graphic data of wiring patterns around the single via cells from the auxiliary storage device 72, and at the same time, reads cell data 77 of multiple via cells from the auxiliary storage device 72 (S40). The data processor 70 extracts points where single via cells are arranged on the basis of read information (S41A). The cell names of the extracted single via cells are unconditionally changed to cell names of first multiple via cells (S42A), and patterns are generated to forcibly rearrange first multiple via cells at the positions of the single via cells using the cell data of the first multiple via cells (S43A). “Forcibly” means that it doesn't matter whether the spatial conditions are satisfied in the surroundings. The above processing is performed for all of the extracted single via cells. For example, it is accepted that a wiring in the Y-direction and a wiring the X-direction are short-circuited as illustrated in FIG. 24.

After that, it is determined whether the spatial conditions are satisfied at points where single via cells have been forcibly replaced with first multiple via cells (S50), wirings which are short-circuited or do not satisfy the minimum space at points where the spatial conditions are not satisfied are cut off (S51), and the cut portions are coupled to wirings of other wiring layers or are detoured using other wirings of the same wiring layer (S52), in order that the spatial conditions are satisfied in the surroundings of the first multiple via cells for which the spatial conditions are not satisfied. When finishing the series of processing, the data processor 70 outputs a message of the effect (S44).

As a result, at first, single via cells are used at connection points between wiring layers, so that vias for coupling the lowest wiring layer of high wiring density including wiring patterns in circuit cells to the upper wiring layer can be initially arranged at a high density, and in this point, the highest priority may be given to a request for high integration of the semiconductor device. In this condition, forcibly replacing single via cells with first multiple via cells can achieve increase of the yield of the semiconductor device more than the case of FIG. 22. However, time for correcting the wiring patterns is needed.

<<First Multiple Via Cells are Arranged from the Start>>

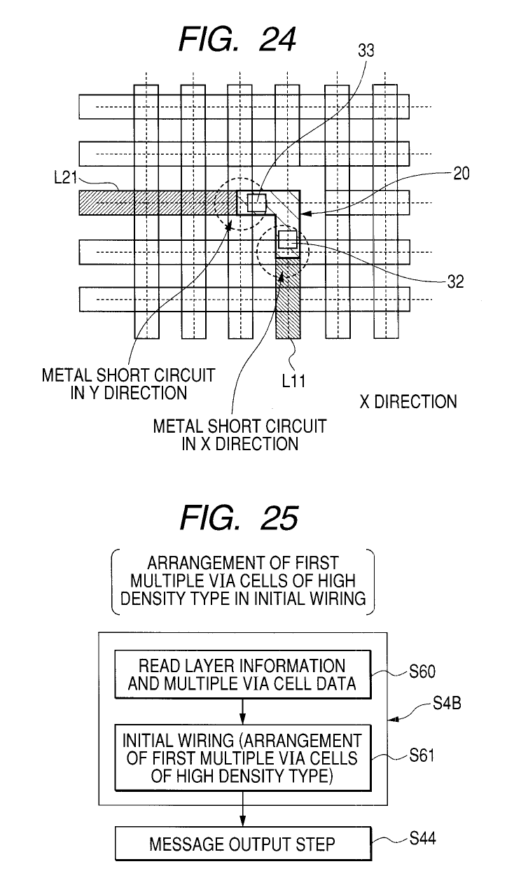

FIG. 25 shows a procedure in the case that first multiple via cells are used from an initial layout of via cells. In this case, single via cells are not used but first multiple via cells are used in the processing of S4B in FIG. 20. The processing S4C is not performed. In other words, as shown in FIG. 25, in the processing of S4B, the data processor 70 reads layer information and multiple via cell data (S60), and arranges first multiple via cells at points where wirings of different wiring layers are coupled (S61).

When the first multiple via cells are used at all connection points between wiring layers from the start, the effect of increase of the yield can be expected most, but high integration of the semiconductor device is sacrificed to some extent.

<<Initially Arranged Single Via Cells are Replaced with Second Multiple Via Cells and then Remaining Via Cells are Forcibly Replaced with First Multiple Via Cells>>

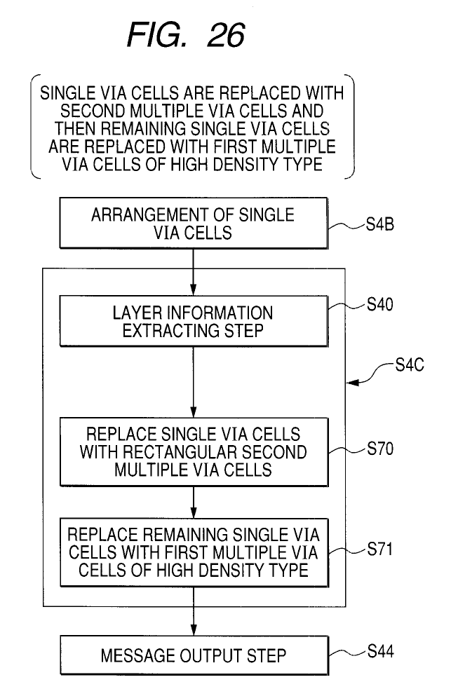

FIG. 26 shows a procedure of selectively replacing initially arranged single via cells with second multiple via cells and then forcibly replacing single via cells which cannot be replaced with second multiple via cells with first multiple via cells. The processing of S4B and S40 is equivalent to that in FIG. 21.

In the processing of S70, the data processor 70 extracts points where single via cells can be replaced with second multiple via cells on the basis of read information. In other words, the data processor 70 determines whether the spatial conditions necessary to replace single via cells at the points with second multiple via cells are satisfied around the single via cells. The spatial conditions include a condition that the wiring is not short-circuited with any other wiring, a condition that the minimum interval is kept between the wiring and any other wiring, a condition that a sufficient interval is kept between the vias and adjacent different potential vias, and the like. When the spatial conditions are satisfied, the cell names of corresponding single via cells are changed to cell names of second multiple via cells, and patterns are generated to rearrange second multiple via cells at the positions of the single via cells using the cell data of the second multiple via cells. The data processor 70 performs the above processing for all of single via cells at extracted locations.

In the subsequent processing of S71, the cell names of single via cells which have been determined not to satisfy the spatial conditions and are remained are unconditionally changed to cell names of first multiple via cells, and patterns are generated to forcibly rearrange first multiple via cells at the positions of the single via cells using the cell data of the first multiple via cells. “Forcibly” means that it doesn't matter whether the spatial conditions are satisfied in the surroundings. The above processing is performed for all of the extracted single via cells. After that, it is determined whether the spatial conditions are satisfied at points where single via cells have been forcibly replaced with first multiple via cells, wirings which are short-circuited or do not satisfy the minimum space at points where the spatial conditions are not satisfied are cut off, and the cut portions are coupled to wirings of other wiring layers or are detoured using other wirings of the same wiring layer, in order that the spatial conditions are satisfied in the surroundings of the first multiple via cells for which the spatial conditions are not satisfied. When finishing the series of processing, the data processor 70 outputs a message of the effect (S44).

As a result, at first, single via cells are used at connection points between wiring layers, so that vias for coupling the lowest wiring layer of high wiring density including wiring patterns in circuit cells to the upper wiring layer can be initially arranged at a high density, and in this point, the highest priority may be given to a request for high integration of the semiconductor device. In this condition, replacing single via cells with second multiple via cells within a possible range and forcibly replacing the remaining single via cells with first multiple via cells can achieve increase of the yield of the semiconductor device more than the case of FIG. 21. However, time for correcting the wiring patterns is needed but less than that in the case of FIG. 23.

<<Initially Arranged Single Via Cells are Replaced with First Multiple Via Cells and then Remaining Via Cells are Forcibly Replaced with Second Multiple Via Cells>>

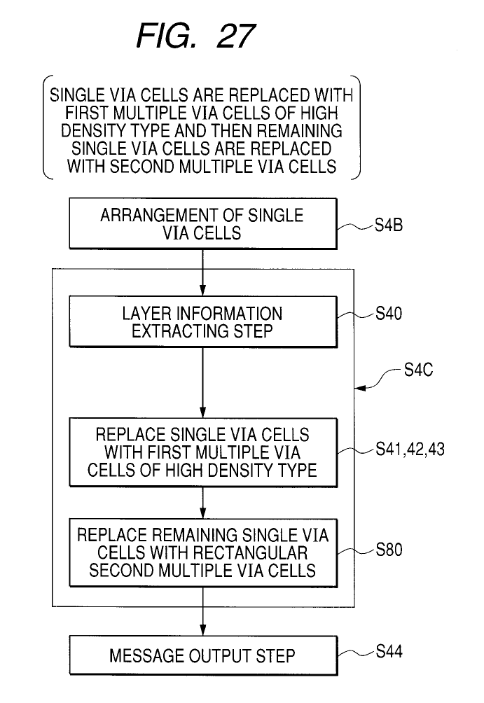

FIG. 27 shows a procedure of selectively replacing initially arranged single via cells with first multiple via cells and then forcibly replacing single via cells which cannot be replaced with first multiple via cells with second multiple via cells. The processing of S4B, S40, S41, S42, and S43 is equivalent to that in FIG. 21. After the processing S43, single via cells are remained at points where it is determined that the spatial conditions are not satisfied. Processing of forcibly rearranging the second multiple via cells instead of the single via cells at these points is performed, and processing of allowing wiring patters around the rearranged second multiple via cells to satisfy the spatial conditions when the second multiple via cells do not satisfy the spatial conditions between the second multiple via cells and the surroundings (S80).

As a result, at first, single via cells are used at connection points between wiring layers, so that vias for coupling the lowest wiring layer at high wiring density including wiring patterns in circuit cells to the upper wiring layer can be initially arranged at a high density, and in this point, the highest priority may be given to a request for high integration of the semiconductor device. In this condition, replacing single via cells with first multiple via cells within a possible range and forcibly replacing the remaining single via cells with second multiple via cells can achieve increase of the yield of the semiconductor device more than the case of FIG. 21. However, time for correcting the wiring patterns is needed but less than that in the case of FIG. 26, because, as described above, in regions of high wiring density, first multiple via cells allows multiplexing of vias also in narrow places, and in regions of low wiring density, first multiple via cells increases the wiring flexibility in the surrounding regions, so that the number of single via cells which cannot be replaced with first multiple via cells and are remained is reduced and consequently the correction points of wiring patterns caused by forcibly replacing the single via cells with second multiple via cells are reduced.

Up to this point, the present invention developed by the present inventor has been concretely described based on the embodiments. However, it is needless to say that the present invention is not limited to the embodiments and various changes and modifications can be made without departing from the spirit and scope of the present invention.

For example, the number of vias provided in a first or second multiple via cell is not limited to two and may be three or more. Only part of vias of a first multiple via cell may be deviated from the intersection of the grid line in the X-direction and the grid line in the Y-direction.

1. A semiconductor device comprising:
a semiconductor substrate;
a first side which is one of the surfaces of the semiconductor substrate
a plurality of circuits arranged on the first side;
a plurality of wiring layers formed above the first side;
a plurality of insulating layers arranged between the first side and the plurality of wiring layers and between each of the plurality of wiring layers; and
a plurality of via holes that couple between the first side and the plurality of wiring layers and between each of the plurality of wiring layers through the a plurality of insulating layers,
wherein the a plurality of via holes couples wirings bent in an L-shape of wiring layers on both sides with the L-shaped bent portion between different wiring layers of the plurality of wiring layers.

2. A semiconductor device having: many circuit cell sections regularly arranged over a semiconductor substrate; terminals of the arranged circuit cell sections formed in a first wiring layer; and a plurality of via cell sections of a first hierarchy for coupling the terminals of the circuit cell sections to a second wiring layer over the first wiring layer, the semiconductor device comprising,
as the via cell section of the first hierarchy, a first multiple via cell section including vias for electrically coupling wirings bent in an L-shape of wiring layers adjacent to one another on both sides with the L-shaped bent portion therebetween,
wherein the vias of the first multiple via cell section are on a grid line in an X-direction and a grid line in a Y-direction defined with a minimum wiring pitch; and
wherein all or part of the vias of the first multiple via cell section are deviated from an intersection of the grid line in the X-direction and the grid line in the Y-direction.

3. The semiconductor device according to claim 2, further comprising,
as the via cell section of the first hierarchy, a second multiple via cell section including a plurality of vias linearly-arranged for electrically coupling wirings of respective wiring layers adjacent to each other extending linearly with insulating layers therebetween,
wherein respective vias of the second multiple via cell section are on a grid line defined with a minimum wiring pitch; and
wherein all or part of the vias of the second multiple via cell section are deviated from an intersection of the grid lines.

4. The semiconductor device according to claim 2, further comprising,
a plurality of via cell sections of a second hierarchy for coupling wirings of the second wiring layer to wirings of a third wiring layer,
wherein the via cell sections of the second hierarchy include the first multiple via cell section.

5. The semiconductor device according to claim 4, further comprising,
a plurality of via cell sections of a third hierarchy for coupling wirings of the third wiring layer to wirings of a fourth wiring layer,
wherein the via cell sections of the third hierarchy include the first multiple via cell section.

6. A semiconductor device having: many circuit cell sections regularly arranged over a semiconductor substrate; terminals of the arranged circuit cell sections formed in a first wiring layer; a plurality of via cell sections of a first hierarchy for coupling the terminals of the circuit cell sections to a second wiring layer over the first wiring layer; and a plurality of via cell sections of a second hierarchy for coupling wirings of the second wiring layer to wirings of a third wiring layer, the semiconductor device comprising,
as the via cell sections of the first and second hierarchies, a first multiple via cell section including vias for electrically coupling wirings bent in an L-shape of wiring layers adjacent to each other on both sides with the L-shaped bent portion therebetween,
wherein the via cell sections of the first hierarchy include the first multiple via cell sections more than the via cell sections of the second hierarchy.

7. The semiconductor device according to claim 6, further comprising:
a plurality of via cell sections of a third hierarchy for coupling wirings of the third wiring layer to wirings of a fourth wiring layer; and
the first multiple via cell sections as the via cell sections of the third hierarchy,
wherein the via cell sections of the second hierarchy include the first multiple via cell sections more than the via cell sections of the third hierarchy.

8. The semiconductor device according to claim 6, further comprising,
as the via cell sections of the first hierarchy, a second multiple via cell section including a plurality of vias linearly-arranged for electrically coupling wirings of respective wiring layers adjacent to one another extending linearly.

9. The semiconductor device according to claim 8, further comprising,
as the via cell sections of the second hierarchy, the second multiple via cell sections.

10. The semiconductor device according to claim 9, further comprising,
as the via cell sections of the third hierarchy, the second multiple via cell sections.

11. The semiconductor device according to claim 6, wherein each of the vias is formed by filling a conductive via plug coupled to wirings of the respective upper and lower wiring layers into a via hole penetrating an insulating layer between the upper and lower wiring layers.

12. A wiring method for a semiconductor device, comprising the process of,
when using a computer to arrange circuit cells necessary for constituting required circuits and then to couple wiring patterns to the arranged circuit cells,
arranging a first multiple via cell including vias for electrically coupling wiring patterns bent in an L-shape of different wiring layers on both sides with the L-shaped bent portion therebetween, at points for coupling wiring patterns of different wiring layers.

13. The wiring method for a semiconductor device according to claim 12, wherein when the first multiple via cell is arranged, the vias of the first multiple via cell section are placed on a grid line in an X-direction and a grid line in a Y-direction defined with a minimum wiring pitch, and all or part of the vias of the first multiple via cell section are deviated from an intersection of the grid line in the X-direction and the grid line in the Y-direction.

14. The wiring method for a semiconductor device according to claim 13, further comprising the processes of:
when using a computer to arrange circuit cells necessary for constituting required circuits and then to couple wiring patterns to the arranged circuit cells,
reading data of the first multiple via cell including the vias for electrically coupling wiring patterns bent in an L-shape of different wiring layers on both sides with the L-shaped bent portion therebetween; and
arranging the first multiple via cell using the data at points for coupling wiring patterns of different wiring layers.

15. The wiring method for a semiconductor device according to claim 13, further comprising the processes of:
when using a computer to arrange circuit cells necessary for constituting required circuits and then to couple wiring patterns to the arranged circuit cells,
reading data of the first multiple via cell including the vias for electrically coupling wiring patterns bent in an L-shape of different wiring layers on both sides with the L-shaped bent portion therebetween;
reading data of single via cells for electrically coupling wiring patterns of different wiring layers using single vias;
arranging the single via cells using the data at points for coupling wiring patterns of different wiring layers;
determining whether or not a spatial conditions necessary for replacing the single via cells with first multiple via cells is satisfied around the arranged single via cells; and
rearranging the first multiple via cells using the data instead of single via cells at points determined to satisfy the spatial conditions.

16. The wiring method for a semiconductor device according to claim 13, further comprising the processes of:
when using a computer to arrange circuit cells necessary for constituting required circuits and then to couple wiring patterns to the arranged circuit cells,
reading data of the first multiple via cell including the vias for electrically coupling wiring patterns bent in an L-shape of different wiring layers on both sides with the L-shaped bent portion therebetween;
reading data of single via cells for electrically coupling wiring patterns of different wiring layers using single vias;
arranging the single via cells using the data at points for coupling wiring patterns of different wiring layers;
rearranging the first multiple via cells using the data instead of the arranged single via cells; and
allowing wiring patters around the first multiple via cells to satisfy the spatial conditions when the rearranged first multiple via cells do not satisfy the spatial conditions between the first multiple via cells and the surroundings.

17. The wiring method for a semiconductor device according to claim 13, further comprising the processes of:
when using a computer to arrange circuit cells necessary for constituting required circuits and then to couple wiring patterns to the arranged circuit cells,
reading data of the first multiple via cell including the vias for electrically coupling wiring patterns bent in an L-shape of different wiring layers on both sides with the L-shaped bent portion therebetween;
reading data of second multiple via cells for electrically coupling wiring patterns of different wiring layers extending linearly using a plurality of vias arranged linearly in parallel;
reading data of single via cells for electrically coupling wiring patterns of different wiring layers using single vias;
arranging the single via cells using the data at points for coupling wiring patterns of different wiring layers;
determining whether or not a spatial conditions necessary for replacing the single via cells with second multiple via cells is satisfied around the arranged single via cells;
rearranging the second multiple via cells using the data instead of single via cells at points determined to satisfy the spatial conditions;
rearranging the first multiple via cells using the data instead of single via cells at points determined not to satisfy the spatial conditions; and
allowing wiring patters around the first multiple via cells to satisfy the spatial conditions when the rearranged first multiple via cells do not satisfy the spatial conditions between the first multiple via cells and the surroundings.

18. The wiring method for a semiconductor device according to claim 13, further comprising the processes of:
when using a computer to arrange circuit cells necessary for constituting required circuits and then to couple wiring patterns to the arranged circuit cells,
reading data of the first multiple via cell including the vias for electrically coupling wiring patterns bent in an L-shape of different wiring layers on both sides with the L-shaped bent portion therebetween;
reading data of second multiple via cells for electrically coupling wiring patterns of different wiring layers extending linearly using a plurality of vias arranged linearly in parallel;
reading data of single via cells for electrically coupling wiring patterns of different wiring layers using single vias;
arranging the single via cells using the data at points for coupling wiring patterns of different wiring layers;
determining whether or not a spatial conditions necessary for replacing the single via cells with first multiple via cells is satisfied around the arranged single via cells;
rearranging the first multiple via cells using the data instead of single via cells at points determined to satisfy the spatial conditions;
rearranging the second multiple via cells using the data instead of single via cells at points determined not to satisfy the spatial conditions; and
allowing wiring patterns around the second multiple via cells to satisfy the spatial conditions when the rearranged second multiple via cells do not satisfy the spatial conditions between the second multiple via cells and the surroundings.

19. A data processing system supporting wiring design for a semiconductor device, comprising:
a data processor executing a program and a storage device,
wherein the data processor, when arranging circuit cells necessary for constituting required circuits and then coupling wiring patterns to the arranged circuit cells, performs the process of arranging first multiple via cells including vias for electrically coupling wiring patterns bent in an L-shape of different wiring layers on both sides with the L-shaped bent portion therebetween, at points for coupling wiring patterns of different wiring layers.

20. The data processing system according to claim 19, wherein when the first multiple via cells are arranged, the vias of the first multiple via cell sections are placed on a grid line in an X-direction and a grid line in a Y-direction defined with a minimum wiring pitch, and all or part of the vias of the first multiple via cell section are deviated from an intersection of the grid line in the X-direction and the grid line in the Y-direction.

21. The data processing system in a semiconductor device according to claim 20,
wherein the data processor, when arranging circuit cells necessary for constituting required circuits and then coupling wiring patterns to the arranged circuit cells, performs the processes of:
reading data of first multiple via cells including vias for electrically coupling wiring patterns bent in an L-shape of different wiring layers on both sides with the L-shaped bent portion therebetween, from the storage device; and
arranging the first multiple via cells using the data at points for coupling wiring patterns of different wiring layers.

22. The data processing system according to claim 20, wherein the data processor, when arranging circuit cells necessary for constituting required circuits and then coupling wiring patterns to the arranged circuit cells, performs the processes of:
reading data of first multiple via cells including vias for electrically coupling wiring patterns bent in an L-shape of different wiring layers on both sides with the L-shaped bent portion therebetween, from the storage device;
reading data of single via cells for electrically coupling wiring patterns of different wiring layers using single vias, from the storage device;
arranging the single via cells using the data at points for coupling wiring patterns of different wiring layers;
determining whether or not a spatial conditions necessary for replacing the single via cells with first multiple via cells is satisfied around the arranged single via cells; and
rearranging the first multiple via cells using the data instead of single via cells at points determined to satisfy the spatial conditions.

23. The data processing system according to claim 20,
wherein the data processor, when arranging circuit cells necessary for constituting required circuits and then coupling wiring patterns to the arranged circuit cells, performs the processes of:
reading, from the storage device, data of first multiple via cells including vias for electrically coupling wiring patterns bent in an L-shape of different wiring layers on both sides with the L-shaped bent portion therebetween;
reading, from the storage device, data of single via cells for electrically coupling wiring patterns of different wiring layers using single vias;
arranging the single via cells using the data at points for coupling wiring patterns of different wiring layers;
rearranging the first multiple via cells using the data instead of the arranged single via cells; and
allowing wiring patters around the first multiple via cells to satisfy the spatial conditions when the rearranged first multiple via cells do not satisfy the spatial conditions between the first multiple via cells and the surroundings.

24. The data processing system according to claim 20,
wherein the data processor, when arranging circuit cells necessary for constituting required circuits and then coupling wiring patterns to the arranged circuit cells, performs the processes of:
reading, from the storage device, data of first multiple via cells including vias for electrically coupling wiring patterns bent in an L-shape of different wiring layers on both sides with the L-shaped bent portion therebetween;
reading, from the storage device, data of second multiple via cells electrically coupling wiring patterns of different wiring layers extending linearly using a plurality of vias arranged linearly in parallel;
reading, from the storage device, data of single via cells for electrically coupling wiring patterns of different wiring layers using single vias;
arranging the single via cells using the data at points for coupling wiring patterns of different wiring layers;
determining whether or not a spatial conditions necessary for replacing the single via cells with second multiple via cells is satisfied around the arranged single via cells;
rearranging the second multiple via cells using the data instead of single via cells at points determined to satisfy the spatial conditions;
rearranging the first multiple via cells using the data instead of single via cells at points determined not to satisfy the spatial conditions; and
allowing wiring patters around the first multiple via cells to satisfy the spatial conditions when the rearranged first multiple via cells do not satisfy the spatial conditions between the first multiple via cells and the surroundings.

25. The data processing system according to claim 20,
wherein the data processor, when arranging circuit cells necessary for constituting required circuits and then coupling wiring patterns to the arranged circuit cells, performs the processes of:
reading, from the storage device, data of first multiple via cells including vias for electrically coupling wiring patterns bent in an L-shape of different wiring layers on both sides with the L-shaped bent portion therebetween;
reading, from the storage device, data of second multiple via cells electrically coupling wiring patterns of different wiring layers extending linearly using a plurality of vias arranged linearly in parallel;
reading, from the storage device, data of single via cells for electrically coupling wiring patterns of different wiring layers using single vias;
arranging the single via cells using the data at points for coupling wiring patterns of different wiring layers;
determining whether or not a spatial conditions necessary for replacing the single via cells with first multiple via cells is satisfied around the arranged single via cells;
rearranging the first multiple via cells using the data instead of single via cells at points determined to satisfy the spatial conditions;
rearranging the second multiple via cells using the data instead of single via cells at points determined not to satisfy the spatial conditions; and
allowing wiring patters around the second multiple via cells to satisfy the spatial conditions when the rearranged second multiple via cells do not satisfy the spatial conditions between the second multiple via cells and the surroundings.
